(19) United States
(12) Patent Application Publication
(10) Pub. No.: US 2007/0178610 A1
(43) Pub. Date: Aug. 2, 2007

(54) Semiconductor Production Apparatus

(76) Inventors: Tatehito Usui, Chiyoda (JP); Motohiko Yoshigai, Hikari (JP); Kazuhiro Joo, Kudamatsu (JP); Shigeru Nakamoto, Kudamatsu (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/696,878

(22) Filed: Apr. 5, 2007

Related U.S. Application Data
(63) Continuation of application No. 10/790,185, filed on Mar. 2, 2004.

(51) Int. Cl. H01L 21/00; H01L 21/306; C23F 1/00; H01L 21/302

(52) U.S. Cl. 438/5; 156/345.24; 156/345.25; 156/345.29; 438/689

(57) ABSTRACT

A semiconductor production apparatus and method for etching a semiconductor wafer arranged in a container and having a film on the surface thereof, by use of a plasma generated in the container. A temporal change of a quantity of an interference light is detected for at least two wavelengths obtained from the surface of the wafer for a predetermined time period of an etching process of the wafer, an etching quantity of the wafer is determined, which varies as long as the etching process proceeds, based upon a particular change arising in the interference light of plural pairs of wavelengths, the plural pairs of the wavelengths corresponding to the etching quantities, respectively.

### CROSS-REFERENCE TO RELATED APPLICATION

This application is a continuation application of U.S. application Ser. No. 10/790,185, filed Mar. 2, 2004, the contents of which are incorporated herein by reference.

The present invention is related to (1) U.S. patent application Ser. No. 10/230,309 filed Aug. 29, 2002 entitled “SEMICONDUCTOR FABRICATING APPARATUS AND METHOD AND APPARATUS FOR DETERMINING STATE OF SEMICONDUCTOR FABRICATING PROCESS” and (2) U.S. patent application Ser. No. 10/377,823 filed Mar. 4, 2003 entitled “SEMICONDUCTOR FABRICATING APPARATUS WITH FUNCTION OF DETERMINING ETCHING PROCESSING STATE”, the entire contents of which is incorporated herein by reference for all purposes.

### BACKGROUND OF THE INVENTION

The present invention relates to an apparatus for producing semiconductor devices by etching, or in particular to a semiconductor production apparatus having the function of determining the state of the etching process such as the etched depth.

In producing a semiconductor device, the dry etching process is widely used in order to remove the layers of various materials such as a dielectric material and an insulating material formed on the surface of a semiconductor wafer or to form a pattern on these layers. In executing the dry etching process, it is crucial to adjust the etching to secure the desired etching depth and the desired film thickness of the layers. For this reason, the end point of etching and the film thickness are required to be detected accurately.

In the process of dry etching a semiconductor wafer using a plasma, the light emission intensity of the light having a specified wavelength contained in the plasma light is known to change with the progress of the etching process for a specific layer. To detect the etching conditions such as the etching end point for the semiconductor wafer or the layer thickness, a technique is known in which the change in light emission intensity of a specific wavelength is detected from the plasma during the dry etching process, and based on the result of this detection, the thickness of a specific layer and the end point of etching the specific layer are detected. In order to improve the accuracy of this detection, it is necessary to reduce the detection error attributable to the change in the detected waveform due to noises.

In recent years, the ever decreasing size and the resulting ever increasing integration of the semiconductor have reduced the opening ratio (the etched area of the semiconductor wafer), and the light emission intensity of a specific wavelength retrieved from the light sensor to the light detector is reduced to a very small level. As a result, the level of the sampling signal from the light detector is reduced, so that it has become more difficult for an end point determining unit to detect the end point of the etching process accurately based on the sampling signal from the light detector.

Also, when stopping the process by detecting the end point of the etching process, it is actually important that the remaining thickness of the dielectric layer be equal to a predetermined value. In the conventional method, the whole process is monitored by use of a time-thickness control technique based on the assumption that the etching rate of each layer is constant. The value of the etching rate is determined, for example, by processing a sample wafer in advance. In this method, the etching process is stopped upon the lapse of a time length corresponding to a predetermined film thickness (the remaining film thickness in the etching process) by the time monitor method.

However, an actual film such as a SiO₂ layer formed by the LPCVD method, for example, is known to have a low thickness reproducibility. The tolerable error of thickness due to the variation during the LPCVD process corresponds to about 10% of the initial thickness of the SiO₂ layer. According to the time monitor method, therefore, the actual final thickness of the SiO₂ layer remaining on the silicon substrate cannot be measured accurately. The actual thickness of the remaining layer is finally measured by a standard spectroscopic interferometer, and in an excessively etched case, the wafer involved is disposed of as a failure.

Techniques for detecting the end point of the semiconductor wafer etching process by measuring the wafer surface using the interferometer are disclosed in JP-A-5-179467 (reference 1), U.S. Pat. No. 5,658,418 (reference 2), JP-A-2000-97648 (reference 3) and JP-A-2000-106356 (reference 4).

In the technique disclosed in JP-A-5-179467 (reference 1), the interference light (plasma light) is detected using three color filters of red, green and blue thereby to detect the etching end point. In the U.S. Pat. No. 5,658,418 (reference 2), on the other hand, the extreme values of the interference waveform (maximum and minimum points of a waveform as a zero-cross point of the differential waveform) are counted using the temporal change of interference waveforms of two wavelengths and differential waveforms thereof. By measuring the time length before the count reaches a predetermined value, the etching rate is calculated, and based on the calculated etching rate, the remaining etching time before a predetermined film thickness is reached is determined thereby to stop the etching process.

In the technique disclosed in JP-A-2000-97648 (reference 3), on the other hand, a waveform representing the difference (with the wavelength as a parameter) between the light intensity pattern (with the wavelength as a parameter) of the interference light before processing and the light intensity pattern of the interference light after or during processing is determined, and a step (film thickness) is measured by comparing the particular difference waveform with the difference waveform stored in a data base. According to JP-A-2000-106356 (reference 4) relating to a rotary coating apparatus, the film thickness is determined by measuring the temporal change of the interference light for multiple wavelengths.

In stopping the process by detecting an etching end point, it is important that the remaining film thickness is actually equal or as near to a predetermined value as possible. In the prior art, the film thickness is monitored by adjusting the time based on the assumption that the etching rate for each layer is constant. The value of the reference etching rate is determined in advance by processing a sample wafer. In this technique, the etching process is stopped upon the lapse of a time length corresponding to a predetermined film thickness.

### SUMMARY OF THE INVENTION

In the case where a small number of semiconductor wafers having a multiplicity of different film structures are processed and fabricated at a time, however, a data base of the multi-wavelength differential interference patterns is required to be prepared for each wafer to be processed as a product. A test etching process conducted using a wafer having the same film structure as an actual wafer would increase the wafer cost, and require as many extraneous wafers as the test processes. In the small-volume production, the problem of a high test cost is posed which increases the device production cost.

In the prior art described above, a sample wafer for thickness measurement is also required to set the operating conditions of a semiconductor production apparatus by detecting the film thickness of the wafer to be processed and to process the product wafer using the thickness detection result. For example, an arbitrary wafer is selectively measured from each lot as a sample wafer. As a result, the extraneous measurement time and wafer are required for a reduced throughput of the semiconductor production.

An object of this invention is to provide a semiconductor production apparatus capable of fabricating semiconductor devices at a lower cost.

Another object of the invention is to provide a semiconductor production apparatus with an improved processing throughput.

The aforementioned objects are achieved by a semiconductor production apparatus for etching a semiconductor wafer arranged in a container and having a film on the surface thereof, using a plasma generated in the particular container, comprising a detector for detecting the temporal change of the amount of the light of at least two wavelengths obtained from the wafer surface for a predetermined length of the processing time, and a determining means for determining the state of the etching process by comparing a predetermined value with the time length between a time point when the temporal change of the amount of the light of one of the two wavelengths described above assumes a maximum value and a time point when the light amount of the light of the other wavelength becomes minimum.

Further, the determining means determines the thickness of the etched film upon determination that the time length described above becomes equal to or shorter than the predetermined value.

Furthermore, the determining means stops the etching process upon determination that the time length described above becomes equal to or shorter than the predetermined value.

The invention is also achieved by a semiconductor production apparatus for etching a semiconductor wafer arranged in a container and having a film on the surface thereof, using a plasma generated in the particular container, comprising a detector for detecting the interference of the light from the wafer surface for a predetermined time length of the etching process, a means for comparing a predetermined value with the time length between a time point when the temporal change of the light amount of one of at least two wavelengths output from the detector becomes maximum and a time point when the light amount of the other wavelength becomes minimum, and a control unit for adjusting the etching process in response to the output from the comparator means.

Further, the control unit stops the etching process in the case where the time length becomes equal to or shorter than the predetermined value.

The invention is also achieved by a semiconductor production apparatus for etching a semiconductor wafer arranged in a container and having a plurality of films including a first film formed on the surface of the semiconductor wafer and a second film formed above the first film, by use of a plasma generated in the container, comprising a light detector for detecting the temporal change of the light amount of a plurality of wavelengths obtained from the wafer surface during a predetermined time length when the second film is etched, and a means for detecting the thickness of the first film based on a specific waveform obtained from the output of the detector.

Further, the detection means detects a unique change of the output of the light detector upon detection by the detector of the temporal change of the amount of the interference light from the wafer surface for a plurality of wavelengths.

Other objects, features and advantages of the invention will become apparent from the following description of the embodiments of the invention taken in conjunction with the accompanying drawings.

### BRIEF DESCRIPTION OF THE DRAWINGS

FIG. 1 is a longitudinal sectional view and a block diagram showing a general configuration of a semiconductor production apparatus according to a first embodiment of the invention.

FIG. 2 is a schematic diagram showing an outline of the configuration of a wafer to be processed and the light interference according to the first embodiment.

FIG. 3 is a graph showing an example of the data obtained using the light interference according to the first embodiment.

FIG. 4 is a diagram showing the operation flow of the processing unit shown in FIG. 1, or especially, the operation flow for adjusting the etching process by detecting the etching condition of the member to be processed.

FIGS. 5A to 5D are diagrams showing the undercoating oxide film dependency of the polysilicon film thickness at which the differential value of the interference light data crosses zero and the undercoating oxide film dependency of the wavelength at which the differential value for the particular thickness crosses zero according to the embodiment shown in FIG. 1.

FIG. 6 shows the polysilicon film thickness dependency of the wavelength at which the interference waveform crosses zero from positive to negative or from negative to positive with an undercoating oxide film group of 1 nm to 10 nm.

FIG. 7 shows a target film thickness area and an approximation line of the zero-crossing wavelength for a the undercoating oxide film thickness group of 270 nm to 340 nm.

FIG. 8 is a diagram showing the operation flow using the result of polysilicon interference waveform analysis for the semiconductor production apparatus according to the embodiment shown in FIG. 1.

FIG. 9 is a diagram showing the undercoating oxide film dependency of the polysilicon film thickness determined by the semiconductor production apparatus according to the embodiment shown in FIG. 1.

FIG. 10 is a diagram showing the operation flow of a semiconductor production apparatus according to another embodiment of the invention.

FIG. 11 is a graph showing an approximation line of the wavelength of the interference waveform.

FIG. 12 is a graph showing an approximation line of the wavelength of the interference waveform.

FIG. 13 is a graph showing an interference waveform obtained from a semiconductor production apparatus according to another embodiment of the invention.

FIGS. 14A and 14B are graphs showing an interference waveform obtained from a semiconductor production apparatus according to still another embodiment of the invention.

FIG. 15 is a flowchart showing the operation flow of the semiconductor production apparatus according to the embodiments shown in FIGS. 13 and 14.

### DETAILED DESCRIPTION OF THE INVENTION

Embodiments of this invention are explained below with reference to the accompanying drawings.

In each of the embodiments described below, those component parts having the same or similar functions as or to those of the first embodiment are designated by the same reference numeral, respectively, as in the first embodiment and are not described in detail. In the embodiments described below, an explanation is given about a method of measuring the etching conditions including the etching amount (etched depth or etched film thickness) in the process of etching a wafer constituting a member to be processed by a semiconductor production apparatus according to this invention.

In the description that follows, the term “film thickness” is defined as the remaining film thickness in the etching process.

### Embodiment 1

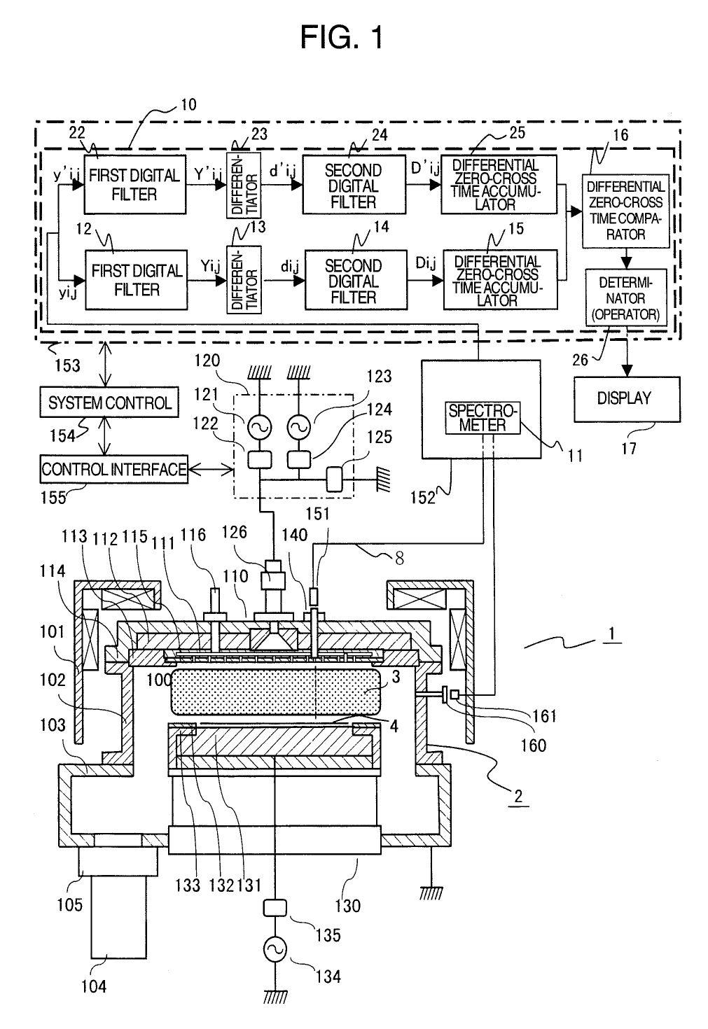

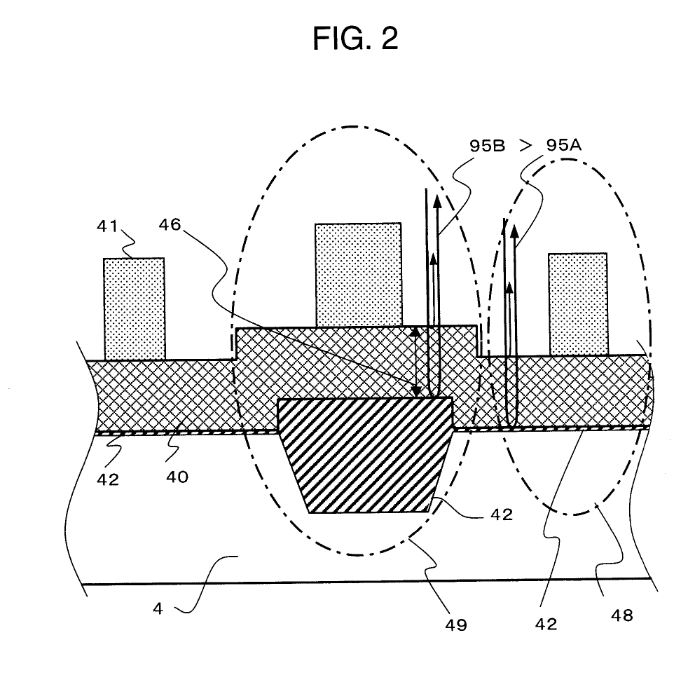

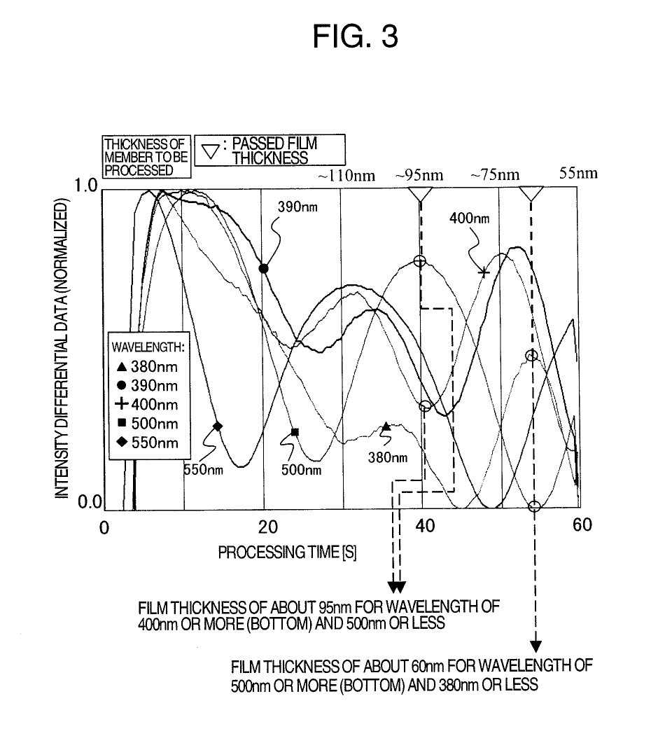

A first embodiment of the invention is explained below with reference to FIGS. 1 to 3. FIG. 1 includes a longitudinal sectional view and a block diagram showing a general configuration of a semiconductor production apparatus according to a first embodiment of the invention. FIG. 2 is a schematic diagram showing the configuration of a wafer to be processed and an outline of the light interference according to the first embodiment. FIG. 3 is a graph showing an example of data obtained using the light interference according to the first embodiment.

First, with reference to FIG. 1, an explanation is given about a general configuration of a processing unit having a film thickness measuring unit for executing the process of etching a semiconductor wafer sample according to this invention.

A processing unit 1 for executing the etching process includes a vacuum container 2. The gas introduced into the vacuum container 2 is converted into a plasma 3 by the electromagnetic wave such as a microwave. A sample 4 constituting a member to be processed such as a semiconductor wafer on a sample table 5 is etched by the plasma 3. According to this embodiment, the multi-wavelength light radiated from a measurement light source (such as a halogen light source) of the film thickness measuring unit 10 is led into the vacuum container 2 by an optical fiber 8 and applied to the sample 4 at an incidence angle substantially at right angles thereto. The member to be processed 4 is a substantially circular flat plate of a semiconductor including a thin film layer of polysilicon in the case under consideration. The radiated light is split into the light reflected and refracted on the upper surface of the polysilicon layer and the light reflected and refracted at the boundary surface formed between the polysilicon layer and an undercoating layer. Both radiated light combine to form an interference light radiated upward of the sample 4. The interference light is led to a spectrometer 11 of the film thickness measuring unit 10 through the optical fiber 8, and based on the detected condition, the film thickness is detected and the process executed to determine an end point.

The film thickness measuring unit 10 includes a spectrometer 11, first digital filter circuits 12, 22, differentiators 13, 23, second digital filter circuits 14, 24, differential waveform data bases (differential zero-cross time point accumulators) 15, 25, a differential waveform comparator (differential zero-cross time comparator) 16, a processing condition determinator (end point determinator) 26 and a result display 17.

In the semiconductor production apparatus according to this embodiment, the member to be processed such as a semiconductor wafer is etched with a plasma in such a manner that a wavelength group of which the differential value of the interference light for a predetermined film thickness crosses zero (or assumes a maximum or minimum value) is selected in advance using the result of calculating the light interference waveform from the optical property values of the member to be processed, and the data on a wavelength group λ1 crossing zero from positive to negative (or assuming a maximum value) and a wavelength group λ2 crossing zero from negative to positive (or assuming a minimum value) are stored or recorded in a storage unit or a recording unit of or communicable with the semiconductor production apparatus. In actually processing the member to be processed 4, the intensity of the interference light of the wavelength groups λ1 and λ2 is measured. A time point at which the differential value of the interference light intensity measurement of each wavelength group crosses zero (assumes an extreme value) is detected. This zero-crossing time point is compared with a predetermined value thereby to determine the film thickness of the member to be processed.

The light emission intensity of a given wavelength included in the wavelength group λ1 retrieved by the light detector 11 is converted into a voltage signal from a current detection signal corresponding to the light emission intensity thereof. The signal of a plurality of specific wavelengths output as a sampling signal from the spectrometer 11 is accommodated as a time series data yij in a storage unit such as a RAM. Next, the time series data yij is smoothed by the first digital filter circuit 12, and stored as a smoothed time series data Yij in a storage unit such as a RAM. Based on the smoothed time series data Yij, the time series data dij of the differential coefficient value (first differential value or second differential value) is calculated by the differentiator 13, and stored in a storage unit such as a RAM. The differential coefficient time series data dij is smoothed by the second digital filter circuit 14, and stored as the smoothed differential coefficient time series data Dij in a storage unit such as a RAM. From this smoothed differential coefficient time series data Dij, a real pattern of the differential values of the interference light intensity of each wavelength is determined.

The light emission intensity of a given one wavelength contained in the wavelength group λ2 retrieved by the light detector 21, on the other hand, is converted into a voltage signal from a current detection signal corresponding to the light emission intensity thereof. A signal of a plurality of specific wavelengths output as a sampling signal from the spectrometer 11 is stored as a time series data y′ij in a storage unit such as a RAM. Next, this time series data y′ij is smoothed by the first digital filter circuit 22, and stored as a smoothed time series data Y′ij in a storage unit such as a RAM. Based on the smoothed time series data Y′ij, the time series data d′ij of the differential coefficient value (first or second differential value) is calculated by the differentiator 23 and stored in a storage unit such as a RAM. The differential coefficient time series data d′ij is smoothed by the second digital filter circuit 24, and stored as a smoothed differential coefficient time series data D′ij in a storage unit such as a RAM. From this smoothed differential coefficient time series data D′ij, a real pattern of the differential value of the interference light intensity of each wavelength is determined.

The differential data storage units 15, 25 have stored therein the interference light intensity data of each wavelength with the change in film thickness or the value and the time point of each waveform of these differential data. Especially, the maximum and minimum values providing a crest and a bottom of the interference waveform (i.e., the zero-cross point of the first differential data waveform) and the time points Tm, T′n thereof are stored. The time length between the time points Tm, T′n is preset in the relational operator 16 or compared with a predetermined value stored or recorded in a storage or a recording unit. In the case where the time length between the time points Tm and T′n is shorter than the predetermined value, it is determined that the remaining film thickness has reached or substantially reached a predetermined size, and the remaining film thickness of the member to be processed is determined. The result is displayed on the display 17.

The present inventors have discovered that when etching a film formed on a semiconductor wafer, a plurality of wavelength groups with one of the interference waveform data thereof assuming a maximum value and the other of the interference waveform data thereof assuming a minimum value can be selected in the neighborhood of the time point associated with a specified film thickness, and that the time length between the time points at which the waveform of the wavelength associated with these groups assumes the maximum and minimum values is decreased with the decrease in film thickness. As a result, the present inventors have come know that it can be determined whether a specific film thickness has been reached or not by presetting the interval between a time point when a maximum value is assumed and a time point when a minimum value is assumed as a reference for the specific film thickness.

The differential data storage unit 15 has stored therein the change of the differential waveform data of the interference light from the sample 4 providing a member to be processed on the one hand and the time points when the interference waveform data assume extreme values (maximum and minimum values, i.e. the zero-cross points of the differential data waveform) on the other hand. Specifically, the data on the time points of the crest and the bottom of the interference light intensity due to the change in film thickness are stored. Also, from the differential data storage unit 15, the data on the differential values of the interference light during a predetermined etching processing time for a predetermined range of wavelength are transmitted to and displayed on the display 17. Further, according to this embodiment, the data on the time points when the differential values of a plurality of interference light wavelengths pass zero (as a maximum value of interference waveform when the first differential value crosses zero from positive to negative sides, and as a minimum value of interference waveform when the first differential value crosses zero from negative to positive sides) are also adapted to be displayed on the display 17.

The film thickness of the member to be processed is also determined by comparing the time point Tm with the time point T′n by the differential waveform comparator 16. The result of comparison is displayed on the result display 17.

This embodiment represents a case involving only one light detector 11. In the case where it is desired to measure and control the internal surface of the member to be processed over a wider area, however, a plurality of light detectors 11 may be used.

FIG. 2 is a longitudinal sectional view of the sample 4 providing a member to be processed such as a semiconductor wafer used for gate etching as an example of the process executed by the processing unit according to this embodiment. In FIG. 2, the member to be processed (polysilicon) 40 constituting a film to be processed is formed on an oxide film 42 providing an undercoating material on the sample (wafer) 4. Further, a mask 41 is stacked on the member to be processed 40. In the case where a gate film is etched on the sample 4, for example, the undercoating material of the member to be processed 40 is an insulating film of SiO₂, and a gate layer of polysilicon is formed on the polycrystal undercoating material between the source and the drain. Also, a device isolating groove 49 for guaranteeing the independent operation of the gate electrode 48 of each device is formed by an oxide film. Further, according to this embodiment, the gate electrode 48 is formed on the side of the device isolation groove (shallow trench isolation, STI) 49 of the oxide film 42 under the mask 41.

The surface of the sample 4 having this configuration is irradiated with the light having a plurality of wavelengths emitted from the spectrometer 11 or the plasma 3, which light enters the sample 4 including a stack structure of the member to be processed 40 and the oxide film 42 providing an undercoating material substantially at right angles thereto. The radiated light which is led to the gate electrode 48 having a thin oxide film (undercoating material) 42 contains a radiated light component reflected on the upper surface of the member to be processed 40 and a radiated light component reflected on the boundary surface formed between the member to be processed 40 and the undercoating material 42. An interference light 95A is formed by the radiated light reflected at these points and radiated upward of the sample 4. In similar fashion, the radiated light which is led to the device isolation portion 49 having a thick undercoating material 42 contains a radiated light component reflected on the upper surface of the member to be processed 40 and a radiated light component reflected on the boundary surface formed between the member to be processed 40 and the undercoating material 42. An interference light 95B is formed by the radiated light reflected at these points and radiated upward of the sample 4. These interference light decrease in interference intensity with the decrease in the thickness of the undercoating oxide film, and therefore the intensity of the interference light 95B is greater than that of the interference light 95A.

The interference light reflected is led to the spectrometer 11 thereby to generate a signal changing in intensity with the thickness of the layer of the member to be processed 40 during the etching process. Among the interference light detected through the spectrometer 11, the interference light 95B from the thick film portion of the undercoating material 42 is more controlling than the interference light 95A. According to this embodiment, the etching factors such as the film thickness and the etched groove depth are detected by the interference light with higher accuracy for those on the device isolation groove 42 (the film thickness 46, etc.).

The display 17 may use a liquid crystal or a CRT or may be replaced or combined with an announcing unit for informing by light or sound that a predetermined film thickness or the end point has been reached. According to this embodiment, the apparatus comprises a display for displaying the measurement data as a graph and the display 17 having a unit using light or sound for announcement.

Further, the apparatus according to this embodiment has the function of displaying the specific information desired by the user who has visually recognized the measurement data indicated on the display 17 or rendering the user to designate the information required to detect or calculate specific information. The function such as a pointer for designating a specific or an arbitrary point on the time-wavelength coordinate indicated on the display 17 or the data thereof, the function of calculating or detecting the data values at the designated points and specific amounts indicating the etching conditions including the time length between specific time points, the wavelength, the etching rate and the film thickness from these data values, and the function of displaying these amounts at a predetermined position in a way easily recognizable by the user, are some examples.

The unit for calculating the above-mentioned amounts may be an operator included in the apparatus or another operator arranged at a remote place with which the apparatus can transmit and receive the measured or detected data through a communication unit.

In FIG. 1, a functional configuration of the device for measuring the etching amount is shown. The actual configuration of the measuring unit 10 except for the display 17 and the spectrometer 11 may include a CPU, a ROM for holding various data including the program for measuring the etching depth and the film thickness and a differential waveform pattern data base of the interference light, a RAM for holding the measurement data, a storage device including an external storage, a data input/output device, and a communication control unit. This is also the case with other embodiments described below.

FIG. 3 is a graph showing the temporal change of the waveform data of the interference light detected by the semiconductor production apparatus according to this embodiment for a plurality of wavelengths. As shown in FIG. 3, it is understood that in a combination of several wavelengths, a wavelength can be selected in which the data assumes a minimum value at about the time point when one of the wavelengths assumes an extreme value (maximum value). The present inventors have come to know that the time difference between the time points when the two wavelengths assume a maximum value and a minimum value, respectively, is reduced with the progress of the process (with the reduction in the remaining film thickness), and that this time difference and the film thickness are correlated and by determining the time difference, it is possible to determine the remaining film thickness (etching (groove) depth) and an end point of the process. This idea has been incorporated in the invention.

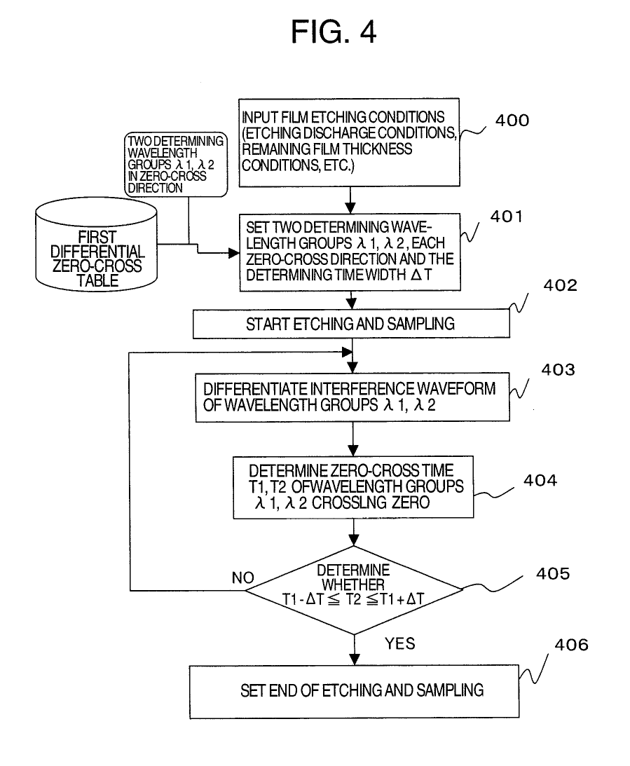

FIG. 4 is a flowchart showing the operation flow of the processing unit shown in FIG. 1, or especially, the operation flow for adjusting the etching process by detecting the etching conditions of the member to be processed.

According to this embodiment, the semiconductor production apparatus acquires in step 800 the conditions for etching the polysilicon film providing the member to be processed 40. In this step, the information may be received from the data base of the processing conditions stored or recorded in a storage unit or a recording unit in advance, or the information may be received which is input by an input device such as a keyboard or a mouse of the display 17 by the user. As another alternative, the data indicating the film configuration recorded in the wafer 4 or the cassette accommodating the semiconductor wafer 4 in advance may be acquired and detected by an operating unit or the like not shown.

Next, in step 401, by use of the data stored in the differential data storage unit or by comparing each waveform stored or recorded in another storage or recording unit with the differential data of each intensity, the wavelength groups λ1 and λ2 for determining the etching condition are detected. Further, a time difference ΔT providing a reference of the time difference between the time points at which the first differential crosses zero is set.

In steps 402, 403 and 404, the process of the wafer 4 is actually started and the waveform data of the interference light obtained during the process is detected. At the same time, the interference waveform of the determining wavelength groups λ1, λ2 set in step 401 are differentiated thereby to calculate the time points T1, T2 at which the differential data of each wavelength group cross zero.

In step 405, the time difference (T1−T2 or T2−T1) between T1 and T2 calculated in step 404 is compared with the time difference ΔT providing a reference set in step 401, by use of the comparator 16. Upon judgment that the relation T1−ΔT [symbol] T2 [symbol] T1+ΔT fails to be met, i.e. that the time difference ΔT is smaller than the time difference between T1 and T2, it is determined that the desired film thickness has not reached, and the process returns to step 403 thereby to continue processing the member to be processed 40. In the case where it is determined that the relation T1−ΔT [symbol] T2 [symbol] T1+ΔT is met, i.e. that the time difference ΔT is larger than or equal to the time difference between T1 and T2, on the other hand, it is determined that the film has reached or decreased below the desired thickness. Then, the process proceeds to step 406 to end the etching process or end the sampling process.

According to this embodiment, the etching is stopped in this step, and so is the sampling of the interference light of the wavelength groups λ1, λ2 through the spectrometer 11.

The present inventors, as the result of studying the interference of the member to be processed (polysilicon film) 40 taking the effect of the undercoating film (oxide film) 42 into consideration, have found that the interference waveform appearing at the time of thickness change during the etching process of the polysilicon 40 is affected by the thickness of the undercoating film (oxide film) 4.

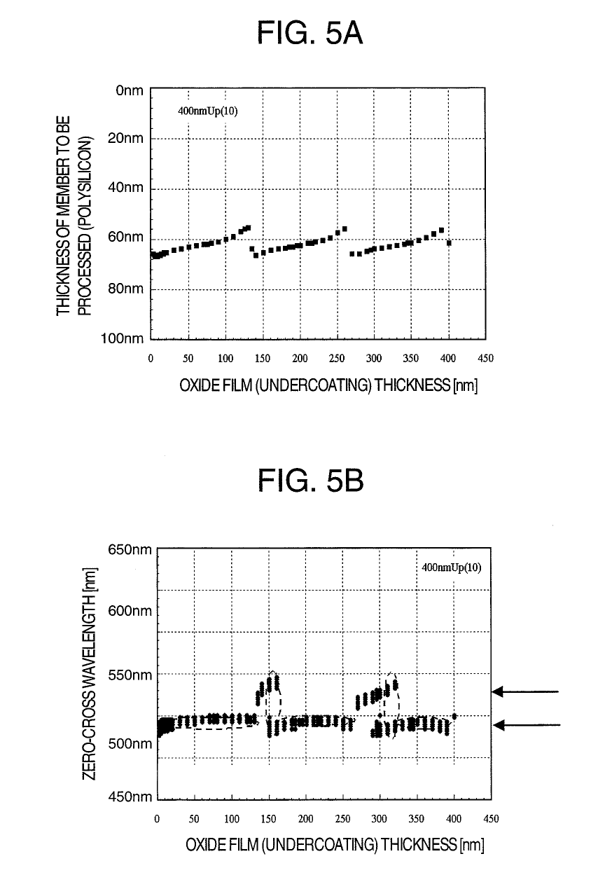

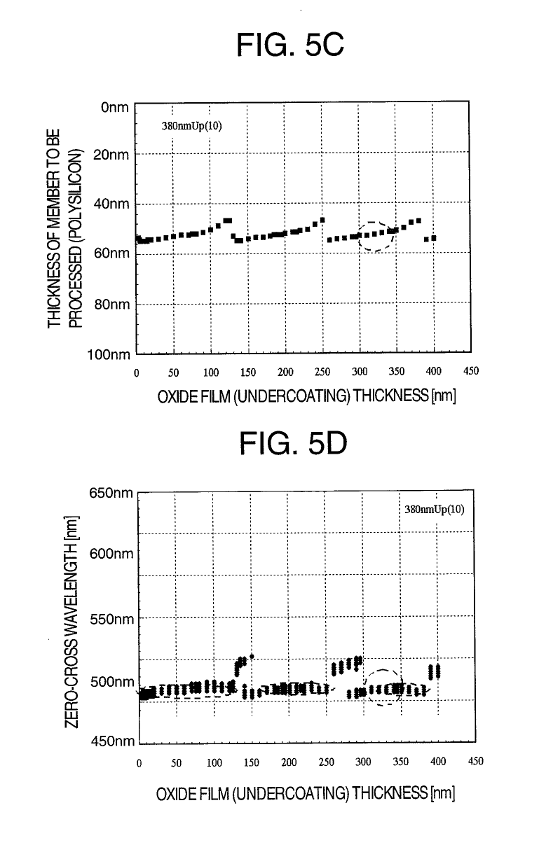

FIGS. 5A to 5D are diagrams the dependency of the polysilicon film thickness on the undercoating oxide film during the etching process in the film thickness measuring unit shown in FIG. 1, whereby the differential value crosses zero from positive to negative side for the data on the interference light having a measured wavelength of 400 nm and a measured wavelength of 380 nm, and the dependency of the wavelength on the undercoating oxide film whereby the differential value crosses from positive to negative for the same film thickness.

FIG. 5A shows the thickness of the polysilicon film 40 about 60 nm thick with the first differential thereof crossing zero from negative to positive (reaches a minimum value), as determined against the thickness of the undercoating oxide film for the light having the wavelength of 400 nm. As shown in FIG. 5A, the polysilicon film thickness undergoes a change as determined for the undercoating oxide film thickness with a periodicity of about 130 nm. This is by reason of the fact that the interference of the polysilicon film is connected so that the interference of the undercoating oxide film continues. Specifically, the periodicity is sin(4πnd/λ), where n is the refractive index of the undercoating oxide film, d the thickness of the undercoating oxide film, and λ the wavelength.

FIG. 5B shows a wavelength group of the interference light which crosses zero from positive to negative (reaches a maximum value) for the polysilicon film thickness at which the light having a wavelength of 400 nm changes by crossing zero from negative to positive. As shown in FIG. 5B, this wavelength group exists over the range of about 430 nm to about 500 nm. By measuring the light having the wavelength of 400 nm and the wavelength group of about 430 nm to 500 nm, therefore, the thickness of the undercoating oxide film can be roughly determined.

In the case where the extreme values for the wavelength 400 nm and the wavelength 440 nm are coincident with each other, for example, the undercoating oxide film is determined as about several nm to 130 nm, about 170 nm to 260 nm or about 330 nm to 380 nm.

In the case where the zero-cross points of the light having a wavelength of 400 nm, the light having a wavelength of 440 nm and the light having a wavelength of 480 nm are coincident with each other, on the other hand, the undercoating oxide film is determined as about 140 nm to 170 nm or about 300 nm to 330 nm. Further, when considering the wafer product specification, the undercoating oxide film thickness is limited more. By use of the undercoating film thickness (about 300 nm to 330 nm) determined in this way, the band of the wavelength group λ2 crossing zero from positive to negative is narrowed from about 410 nm to 420 nm (from about 410 nm to 450 nm) when the measured wavelength 380 nm shown in FIG. 5C crosses zero from negative to positive (FIG. 5D). At the same time, the polysilicon film thickness thus far determined as about 48 nm to 56 nm is changed to about 52 nm to 55 nm for an improved accuracy.

In the case where it is desired to control the member to be processed by measuring the surface thereof over a wide area, a plurality of spectrometers may be used.

Also, the interference light may be measured by a measuring unit such as a spectrometer 11 using the light from the plasma 3 generated in the vacuum container 2 without using the light source for supplying the light into the vacuum container 2 as in the embodiment described above. In such a case, the plasma light reflected from the surface of the sample 4 is supplied to the spectrometer 11. In order to measure the change in the plasma light, a measurement port or an optical transmission unit is arranged on the side wall of the vacuum container 2 in such a manner as to be capable of receiving the inner light, whereby the detected signal is used as a reference light. This reference light is not passed through the light path directly incident from the surface of the sample 4, and the change in the light from the plasma 3 is required to be detected. According to this embodiment, the light from the plasma 3 is received by a photodetector arranged on the side wall of the vacuum container 2.

Analysis of the interference of the member to be processed (polysilicon film) 40 taking the effect of the undercoating film (oxide film) 42 into consideration shows that the interference waveform appearing when the film thickness changes at the time of etching the polysilicon 40 can be divided into groups by the thickness of the undercoating film (oxide film) 4, and by selectively setting the groups, the thickness of the polysilicon film during the etching process can be easily measured.

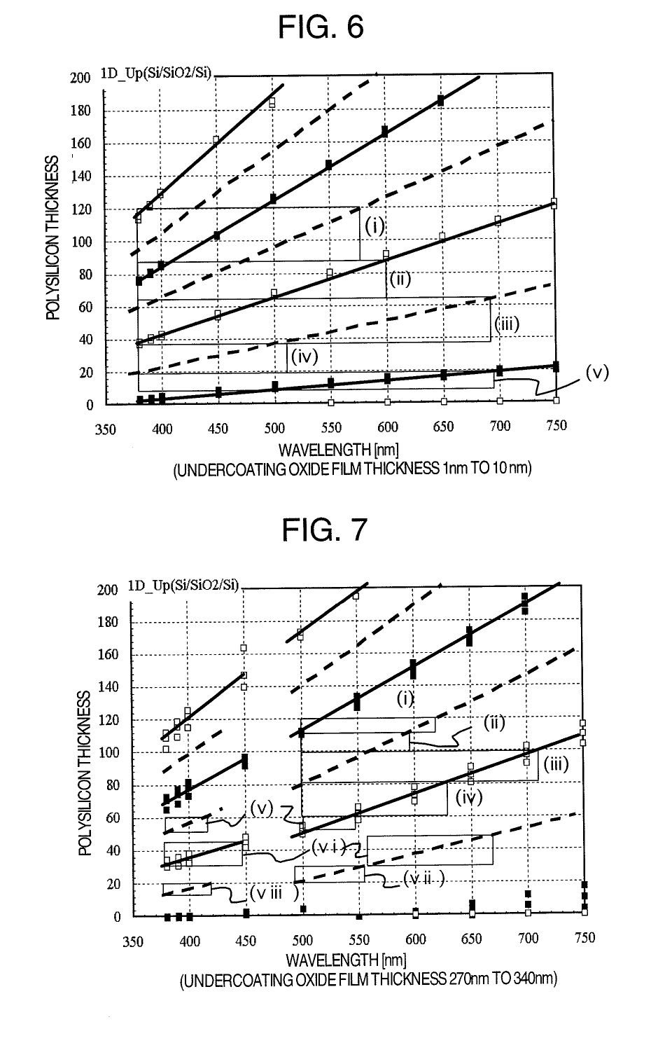

Next, an embodiment using this simple method is explained. FIG. 6 shows the polysilicon film thickness dependency of the wavelength for which the interference waveform groups for the undercoating oxide film thickness of 1 nm to 10 nm cross zero from positive to negative or from negative positive side. In FIG. 6, the solid lines indicate the first differential of the interference waveform crossing zero from negative to positive side, and the dashed line indicates the first differential of the interference waveform crossing zero from positive to negative side. The marks □ indicate the maximum, minimum and average polysilicon film thickness crossing zero from negative to positive side. As shown in FIG. 6, the wavelength for which the first differential crosses zero changes substantially linearly with the polysilicon film thickness. By using these approximation lines, therefore, the wavelength for which the first differential crosses zero can be determined with a target film thickness. With regard to the target film thickness of 50 nm, for example, the interference waveform having a wavelength of about 425 nm crosses zero from negative to positive side, while the interference waveform having a wavelength of about 575 nm crosses zero from positive to negative side.

The rectangular frames (i) to (v) shown in FIG. 6 indicate areas for selecting an approximation line to determine the zero-cross wavelength for film thickness determination against a target film thickness. Specifically, a wavelength crossing zero from negative to positive side for the target film thickness area (120 to 88 nm) is determined as y=0.4026x−76.488, and as y=0.3141x−62.428 for a wavelength crossing zero from positive to negative side, where y is a target film thickness and x a zero-crossing wavelength. Also, the wavelength crossing zero from negative to positive side is determined as y=0.2269x−47.479 and the wavelength crossing zero from positive to negative side as y=0.3141x−62.428 for the target film thickness area (88 to 65 nm), the wavelength crossing zero from negative to positive side is determined as y=0.2269x−47.479 and the wavelength crossing zero from positive to negative side as y=0.1418x−33.871 for the target film thickness area (65 to 38 nm), the wavelength crossing zero from positive to negative side is determined as y=0.1418x−33.871 for the target film thickness area (38 to 20 nm), and the wavelength crossing zero from negative to positive side is determined as y=0.0495x−15.548 for the target film thickness area (20 to 10 nm).

By dividing into groups by the undercoating oxide film thickness and selectively setting the approximation line of the zero-crossing wavelength for each target film thickness in this way, an algorithm can be constructed for more accurate film thickness determination.

FIG. 7 shows approximation lines of the zero-crossing wavelength and target film thickness areas for the group having an undercoating oxide film thickness of 270 nm to 340 nm. The rectangular frames (i) to (viii) shown in FIG. 7 also indicate areas for selecting an approximation line to determine the zero-cross wavelength for film thickness determination against a target film thickness. In this group, a theoretical interference analysis of the member to be processed (polysilicon film) 40 taking the effect of the undercoating film (oxide film) 42 into consideration shows that the interference wavelength of about 450 nm to 500 nm is distorted by the periodicity (about 130 nm) of interference due to the undercoating oxide film. It has thus been found that in setting a film thickness determining wavelength, the approximation line is required to avoid the wavelength range of about 450 nm to 500 nm to avoid a determination error due to the distortion.

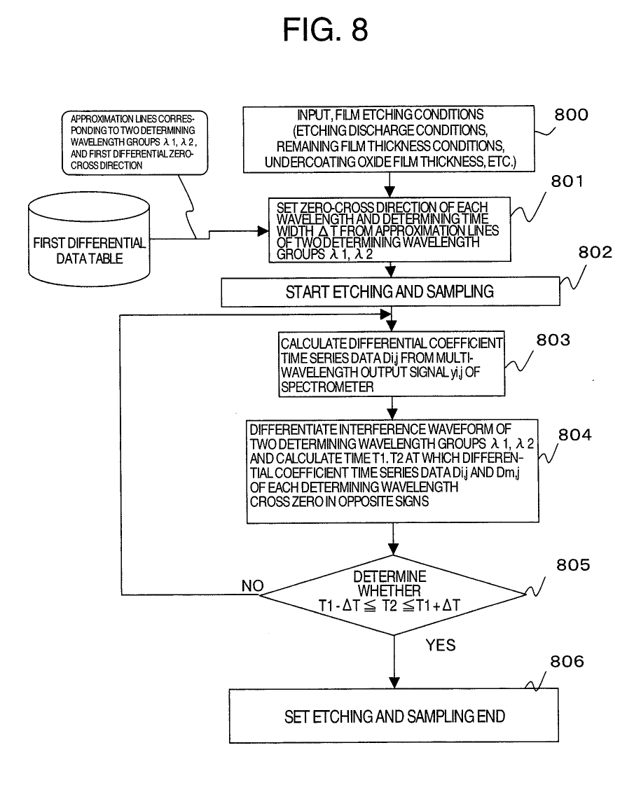

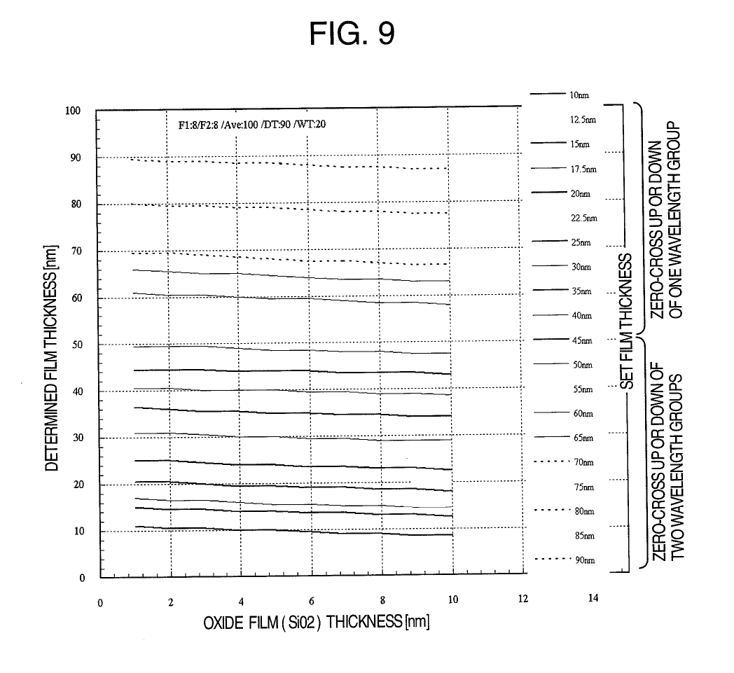

FIG. 8 shows the operation flow of a processing unit using the result of the aforementioned interference waveform analysis of polysilicon, or especially, the operation flow for adjusting the etching process by detecting the etching condition of the member to be processed.

In FIG. 8, the semiconductor production apparatus according to this embodiment acquires in step 800 the conditions (the etching discharge conditions, the target remaining film thickness, and the undercoating oxide film thickness) for etching the polysilicon film providing a member to be processed 40. Next, in step 801, the wavelengths of the two wavelength groups λ1, λ2 used for determining the etching conditions are determined by an approximation line capable of calculating the wavelength of which the first differential of the target film thickness stored or recorded as a data table of the data base in the storage or recording device in advance crosses zero from negative to positive side and an approximation line for calculating the wavelength of which the first differential crosses zero from positive to negative side. Further, a reference time difference dT is set for these wavelengths, the zero-cross direction and the time difference between time points at which the extreme values in opposite signs are assumed.

In steps 802, 803 and 804, the actual processing of the wafer 4 is started, and the interference light waveform data (such as the actual waveform, the time series data of the waveform after differentiation, etc.) obtained during the same process are detected. At the same time, the interference waveform of the determining wavelength groups λ1, λ2 set in step 801 are differentiated. In this way, time points t1, t2 are calculated at which the differential data of each wavelength crosses zero in opposite signs for each wavelength (i.e. the time points at which the one of the first differentials crosses zero from negative to positive side, and the other first differential crosses zero from positive to negative side).

In step 805, the time difference between T1 and T2 (T1−T2 or T2−T1) calculated in step 804 is compared with the reference time difference dT set in step 801 by a comparator 16. In the case where it is determined that the relation |T1−T2| [symbol] dT fails to be met, i.e. that the time difference dT is smaller than the time difference between T1 and T2, it is determined that the desired film thickness is not reached. Then, the process returns to step 803 and the processing of the member to be processed 40 is continued. In the case where it is determined that the relation |T1−T2| [symbol] dT is met, i.e. that the time difference dT is larger or equal to the time difference between T1 and T2, on the other hand, it is determined that the film thickness has reached or decreased below the desired one, so that the process proceeds to step 806 at which the etching end and the sampling end are set.

According to this embodiment, the etching is stopped at this point, and so is the sampling of the interference light of the wavelength groups λ1, λ2 through the spectrometer 11.

FIG. 9 shows the undercoating oxide film dependency of the polysilicon film thickness determined according to an embodiment of this invention. It is seen from FIG. 9 that the polysilicon film thickness (in the range of 90 nm to 10 nm) for the undercoating oxide film area of 1 nm to 10 nm can be determined with an accuracy of about ±2 nm.

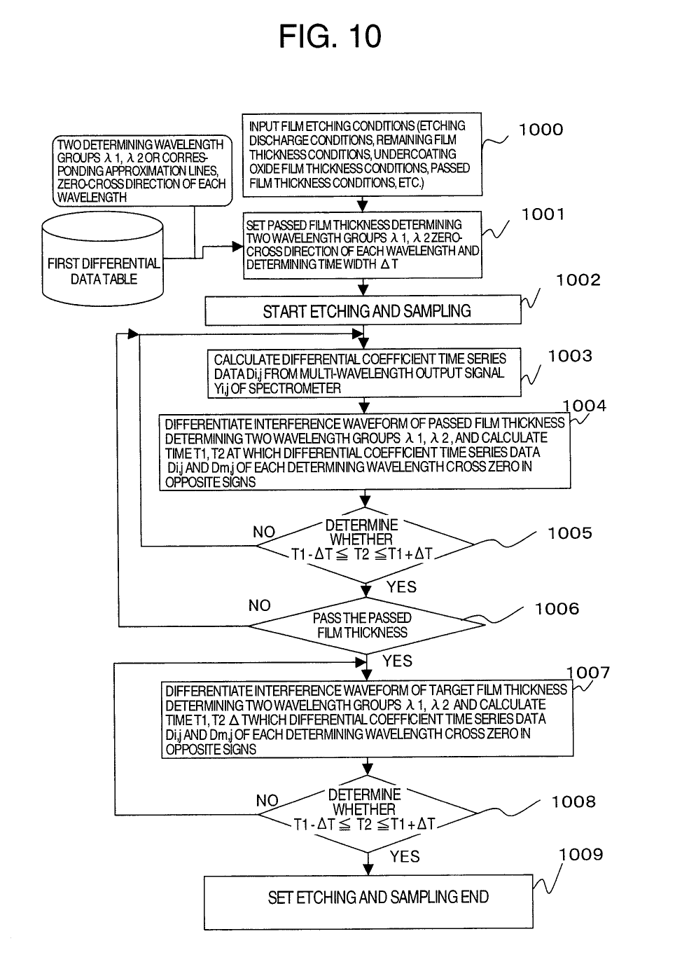

Another embodiment of the invention is explained with reference to FIG. 10. According to this embodiment, the fact that a film thicker than a target film thickness has been etched, i.e. a film thickness greater than the target film thickness has been passed is detected to improve the reliability of film thickness determination. For the present purpose, the film thickness greater than the target film thickness is called a passed film thickness. By detecting the passed film thickness and starting the determination of the target film thickness, a determination error which might occur for a small target film thickness is prevented.

According to this embodiment, the semiconductor production apparatus acquires the conditions (the etching discharge conditions, the target remaining film thickness and the undercoating oxide film thickness, etc.) for the process of etching a polysilicon film providing the member to be processed 40. Next, in step 1001, a determining wavelength having two wavelength groups is obtained from the wavelength at which the first differential of the target film thickness stored or recorded in a storage unit or a recording unit crosses zero from negative to positive side or the information on the approximation line for determining the same wavelength, and the wavelength at which the first differential crosses zero from positive to negative side or the information on the approximation line for determining the same wavelength. Then, a reference time difference dT is set for the wavelengths, the zero-cross direction thereof and the time difference between the time points assuming the opposite extreme values.

Further, with regard to the passed film thickness set in accordance with the target film thickness, a determining wavelength having two wavelength groups is obtained from the wavelength at which the first differential of the passed film thickness stored or recorded in a storage unit or a recording unit crosses zero from negative to positive side or the information on the approximation line for determining the same wavelength, and the wavelength at which the first differential crosses zero from positive to negative side or the information on the approximation line for determining the same wavelength, thereby setting the particular wavelength and the zero-cross direction thereof. For the target film thickness of 10 nm of the undercoating oxide film group of 1 nm to 10 nm, for example, the corresponding passed film thickness for the target film thickness are 100 nm, 50 nm and 40 nm. The determining wavelength for the passed film thickness 100 nm is set at 430 nm for detection of a zero cross point from positive to negative side and at 510 nm for detection of a zero cross point from negative to positive side, the determining wavelength of the passed film thickness 50 nm is set at 425 nm for detection of a zero cross point from positive to negative side and at 580 nm for detection of a zero cross point from negative to positive side, the determining wavelength of the passed film thickness 40 nm is set at 380 nm for detection of a zero cross point from positive to negative side and at 500 nm for detection of a zero cross point from negative to positive side, and the determining wavelength of the target film thickness is set at 500 nm for detection of a zero cross point from positive to negative side. By determining the target film thickness after detection of the passed film thickness in this way, the determining wavelength can detect the zero cross point from positive to negative side at 500 nm without error.

In steps 1002, 1003 and 1004, the actual processing of the wafer 4 is started and the interference light waveform data obtained during this process is detected. At the same time, the interference waveform of the two wavelength groups for the passed film thickness set in step 1001 is differentiated thereby to calculate the time points t1 and t2 at which the differential data for the respective wavelength groups assumes extreme values.

In step 1005, as described above, the time difference (t1−t2 or t2−t1) between t1 and t2 calculated in step 1004 is compared with the reference time difference dT set in step 1101, by the comparator 16. In the case where it is determined that the relation |t1−t2| [symbol] dT fails to be met, i.e. that the time difference dT is smaller than the time difference between t1 and t2, it is determined that the desired passed film thickness is not reached. Then, the process returns to step 1003 to continue the processing of the member to be processed 40. In the case where it is determined that the relation |t1−t2| [symbol] dT is met, i.e. that the time difference dT is larger than or equal to the time difference between t1 and t2, it is determined that the film thickness has reached or decreased below the desired one. Further, the process proceeds to step 1006, where it is determined whether all the passed film thickness that have been set are passed and a target film thickness has been approached or not. In the case where a passed film thickness to be passed before the target film thickness is set, the process returns to step 1003 to determine whether the passed film thickness has been passed or not.

In the case where it is determined that all the passed film thickness have been passed, the process proceeds to step 1007 where in order to detect whether the target film thickness has been reached or not, like in steps 1000 to 1005, the interference light waveform data obtained by processing the wafer 4 is detected, and the interference waveform of the two wavelength groups for determining the target film thickness set in step 1001 is differentiated. In this way, the time points T1 and T2 are calculated at which the differential data assumes an extreme value in each wavelength group.

In step 1008, the time difference between T1 and T2 (T1−T2 or T2−T1) calculated in step 1107 is compared by the comparator 16 with the reference time difference dT set in step 1001. In the case where it is determined that the relation |T1−T2| [symbol] dT fails to hold, i.e. that the time difference dT is smaller than the time difference between T1 and T2, it is determined that the film thickness has not reached the desired amount. Then, the process returns to step 1007 to continue the processing of the member to be processed 40. Once it is determined that the relation |T1−T2| [symbol] dT holds, i.e. that the time difference dT is larger than or equal to the time difference between T1 and T2, on the other hand, it is determined that the film thickness has reached or decreased below the desired amount. Then, the process proceeds to step 1009 to set the end of etching and sampling. According to this embodiment, the etching is stopped at this point, and so is the sampling of the interference light through the spectrometer 11.

To determine a target film thickness, a plurality of passed film thickness may be set and the target film thickness is predicted from these passed film thickness and the passed time thereof thereby to end the etching process. For example, the passed film thickness is set at each 10 nm in the range of 100 nm to 30 nm and the passed time is measured for each passed film thickness. A regression line is determined, for example, using the passed film thickness and the passed time, and from this regression line, the time point at which the target film thickness is reached is calculated and used for determination.

In the measurement of the interference waveform, the light amount of a light source for obtaining the interference light or the plasma light amount may undergo an abrupt change. In such a case, the interference wavelength other than the two wavelength groups for film thickness determination are measured at the same time, and it is determined whether the first differential of the interference waveform assumes a positive (or negative) value or not. This detection can prevent an erroneous determination of the interference wave in the case where a similar change like that of light described above occurs in all the wavelength ranges.

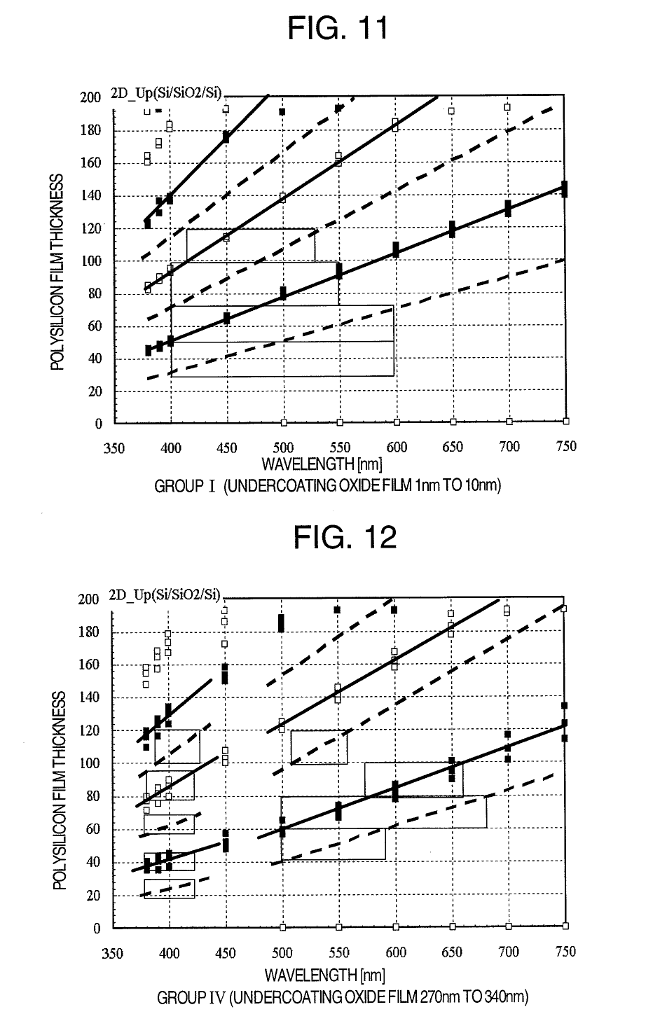

The wavelength of the interference waveform for preventing the erroneous determination of the interference waveform can be determined from the inflection point of the interference waveform, i.e. the point at which the second differential crosses zero. FIGS. 11 and 12 show the approximation lines of the interference wavelength for preventing the erroneous determination of the interference waveform for the undercoating oxide film group of 1 nm to 10 nm and the undercoating oxide film group of 270 nm to 340 nm.

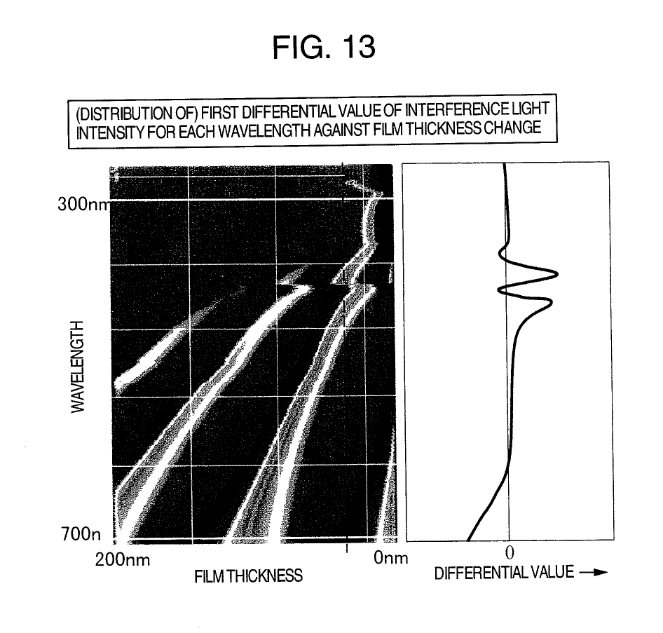

Other embodiments of the invention are explained below with reference to FIGS. 13, 14A, 14B and 15.

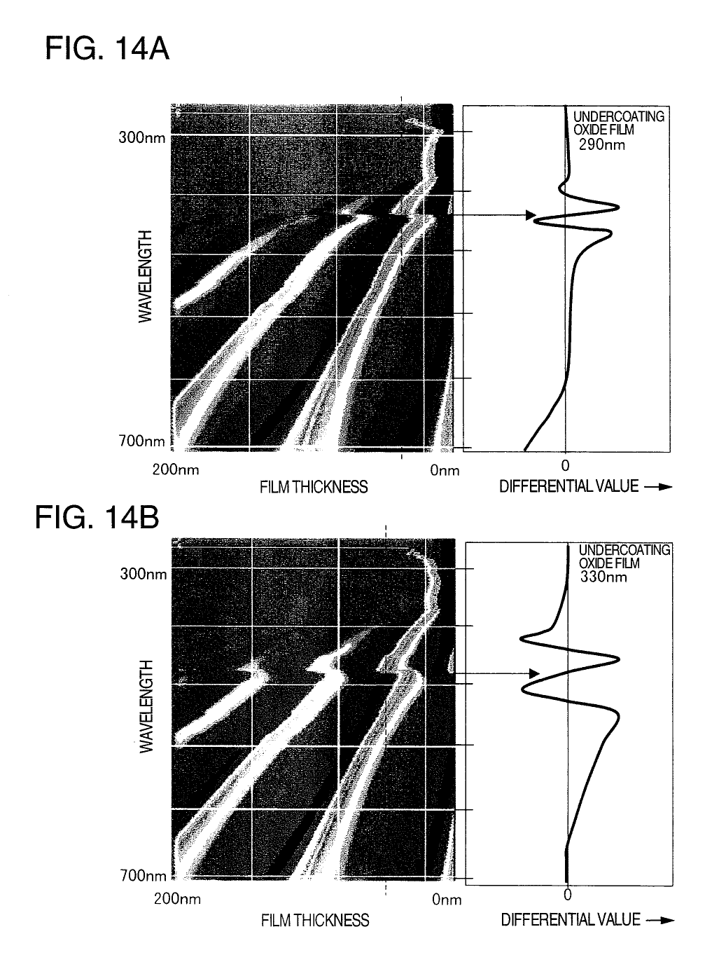

FIGS. 13, 14A and 14B are diagrams showing interference waveforms detected by the semiconductor production apparatus according to other embodiments of the invention. In FIG. 13, the left graph shows the intensity change of the interference light with the ordinate representing the wavelength and the abscissa representing the film thickness (processing time), and the right graph shows the intensity change of the wavelength range of less than 300 nm to 700 nm or more at a specified time point indicated by dotted line in the left graph.

As shown in FIG. 13, the interference light undergoes a sharp change at about a specific wavelength with the differential data of the intensity greatly changing vertically. FIGS. 14A and 14B, like FIG. 13, shows the intensity change of the interference light with the ordinate representing the wavelength and the abscissa the film thickness (processing time). FIG. 14A shows the case in which the thickness of the oxide film 42 formed under the polysilicon providing the member to be processed 40 is 290 nm, and FIG. 14B shows the case in which the undercoating oxide film is 330 nm. As seen from these diagrams, the present inventors have come to know that the value of the wavelength with the intensity of the differential data of the interference light greatly changing vertically undergoes a change depending on the thickness of the undercoating oxide film 42, and the wavelength and the thickness of the undercoating oxide film 42 are correlated with each other, so that the thickness of the underlying oxide film can be detected using the interference light data obtained at the time of etching the member to be processed located above the oxide film. This embodiment of the invention is conceived based on this knowledge.

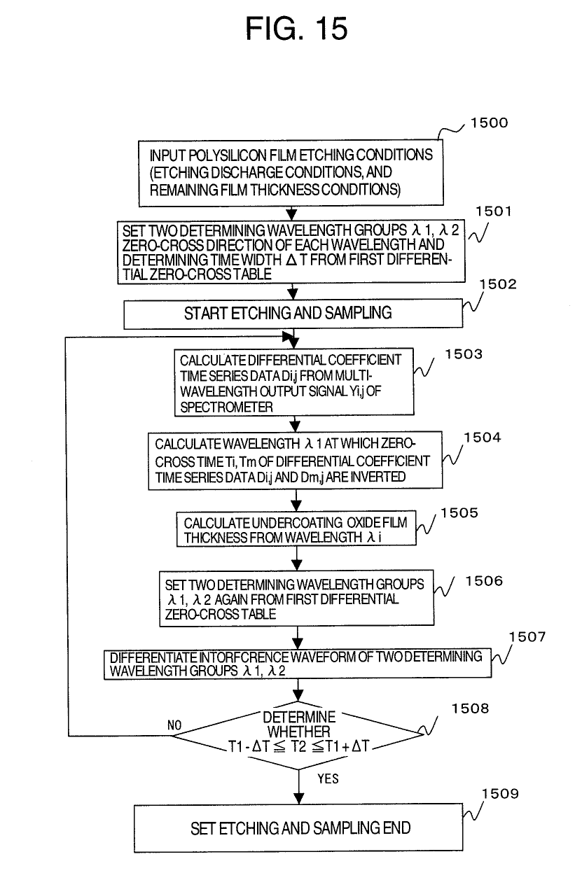

FIG. 15 is a flowchart showing the operation flow of a semiconductor production apparatus according to an embodiment in which the interference waveforms shown in FIGS. 13, 14A and 14B are obtained. According to this embodiment, at the time of etching a polysilicon gate, the interference light intensity of a wavelength range of about 300 nm to 700 nm is detected thereby to obtain the differential data thereof. The thickness of the undercoating oxide film is calculated from the inverted waveform crossing zero (assuming an extreme value) when the thickness of the polysilicon film 40 to be processed is reduced, by utilizing not the fact that the property of the particular wavelength shifts sequentially toward the short wavelength side but the fact that the shorter wavelength inverts before the longer one due to the undercoating oxide film thickness.

As a result, the thickness of the underlying film (undercoating oxide film) that has thus far been determined by selectively measuring the wafer providing an arbitrary sample can be detected using the interference light data when the upper film is processed. Therefore, the throughput that has been reduced for measuring the sample can be suppressed while at the same time preventing the production cost from increasing.

Thus, the accuracy can be improved for determining a predetermined film thickness of the polysilicon providing a member to be processed, using the thickness of the undercoating oxide film calculated as described above.

FIG. 15 shows a process in which the etching conditions (the etching discharge conditions, and the remaining film thickness conditions) for the member to be processed (polysilicon) are input (step 1500), and the two determining wavelength groups λ1, λ2 with the zero-cross direction and the determining time width ΔT are set from the data stored in the data storage unit based on the remaining film thickness conditions (step 1501).

Next, the wafer 4 begins to be etched and sampled (step 1502), the differential coefficient time series data Di,j are calculated based on the multi-wavelength output signal yi,j from the spectrometer (step 1503), and the wavelength λi is calculated at which the zero-cross time Ti and Tm of the differential coefficient time series data Di,j and Dm,j are inverted (step 1504), where i indicates the wavelength measured on the long wavelength side, and m the wavelength measured on the short wavelength side.

In the wavelength range not affected by the undercoating oxide film, the relation Ti<Tm holds between time Ti and time Tm, while the relation between time Ti and time Tm is Ti>Tm in the wavelength range affected by the undercoating oxide film. The thickness of the undercoating oxide film is calculated from the wavelength λi by the distorted wavelength value and the undercoating oxide film thickness held in the data base (step 1505). Using the calculated thickness of the undercoating oxide film, the two determining wavelength groups λ1, λ2 are set again from the differential zero-cross table (step 1506).

The interference waveform of the two determining wavelength groups λ1, λ2 set again are differentiated (step 1507).

Next, the reference time difference ΔT set in step 901 is compared with the time difference between the zero-cross time points T1 and T2, i.e. it is determined whether the relation T1−ΔT [symbol] T2 [symbol] T1+ΔT is held or not (step 1508) thereby to set the end of etching and sampling (step 1509). In the case where the result of comparison between the time difference ΔT and the time difference between the zero-cross time points T1 and T2 (i.e. determination as to whether the relation T1×ΔT [symbol] T2 [symbol] T1+ΔT is held or not in step 1508) is NO, the process is repeated from step 1503.

Once the thickness of the undercoating oxide film can be calculated, however, the process of steps 1503 to 1505 is not necessarily executed.

In the case where the determination in step 1508 is YES, on the other hand, the process proceeds to step 1509 for setting the end of etching and sampling.

As described above, unlike in the prior art wherein the processing throughput is reduced with an increased cost by the measurement using a sample wafer, the present invention is such that the thickness of the undercoating film can be detected from the data obtained at the time of processing the upper film as a product. Thus, the overall processing throughput including the apparatus is improved and the cost increase is suppressed.

It should be further understood by those skilled in the art that although the foregoing description has been made on embodiments of the invention, the invention is not limited thereto and various changes and modifications may be made without departing from the spirit of the invention and the scope of the appended claims.

What is claimed is:

1. A semiconductor production apparatus for etching a semiconductor wafer arranged in a container and having a film on the surface thereof, by use of a plasma generated in the container, comprising:
a detector which detects a temporal change of a quantity of an interference light for at least two wavelengths obtained from the surface of the wafer for a predetermined time period of an etching process of the wafer; and
a determining device which determines an etching quantity of the wafer, which varies as long as the etching process proceeds, based upon a particular change arising in the interference light of plural pairs of wavelengths, the plural pairs of the wavelengths corresponding to the etching quantities, respectively, and the particular change being detected by using detected results obtained from the detector.

2. A semiconductor production apparatus according to claim 1, further comprising a control unit which adjusts the etching process based upon the determination of the determining device which is made after that a first etching quantity of the wafer is determined based upon the particular change arising in the interference light of a first pair of wavelengths, and based upon the particular change arising in the interference light of a second pair of wavelengths different from the first pair of wavelengths.

3. A semiconductor production apparatus according to claim 2, wherein the determining device determines the predetermined etching quantity based on a time point at which data corresponding to the interference light of one of the wavelengths assumes a maximum value and a time point at which data corresponding to the interference light of the other of the wavelengths assumes a minimum value, both of which are within a predetermined time period.

4. A semiconductor production apparatus according to claim 2, wherein the determining device determines the predetermined etching quantity based on a time point at which a differential value obtained by differentiating time series data from the detector corresponding to the interference light of one of the wavelengths makes a zero-crossing from positive to negative and a time point at which a differential value corresponding to the interference light of the other of the wavelengths makes a zero-crossing from negative to positive, both of which are within a predetermined time period.

5. A semiconductor production method for etching a semiconductor wafer arranged in a container and having a film on the surface thereof, by use of a plasma generated in the container, comprising the steps of:
detecting a temporal change of a quantity of an interference light for at least two wavelengths obtained from the surface of the wafer for a predetermined time period of an etching process of the wafer; and
determining an etching quantity of the wafer, which varies as long as the etching process proceeds, based upon a particular change arising in the interference light of plural pairs of wavelengths, the plural pairs of the wavelengths corresponding to the etching quantities, respectively, and the particular change being detected by using detected results obtained in the step of detecting.

6. A semiconductor production method according to claim 5, further comprising the step of adjusting the etching process based upon the determination of the determining device which is made after that a first etching quantity of the wafer is determined based upon the particular change arising in the interference light of a first pair of wavelengths, and based upon the particular change arising in the interference light of a second pair of wavelengths different from the first pair of wavelengths.

7. A semiconductor production method according to claim 6, wherein the step of determining includes determining the predetermined etching quantity based on a time point at which data corresponding to the interference light of one of the wavelengths assumes a maximum value and a time point at which data corresponding to the interference light of the other of the wavelengths assumes a minimum value, both of which are within a predetermined time period.

8. A semiconductor production method according to claim 6, wherein the step of determining includes determining the predetermined etching quantity based on a time point at which a differential value obtained by differentiating time series data from the detector corresponding to the interference light of one of the wavelengths makes a zero-crossing from positive to negative and a time point at which a differential value corresponding to the interference light of the other of the wavelengths makes a zero-crossing from negative to positive, both of which are within a predetermined time period.
